(19) United States
(12) Patent Application Publication
(10) Pub. No.: US 2021/0241392 A1
(43) Pub. Date: Aug. 5, 2021

(54) METRICS FOR ENERGY SAVING AND RESPONSE BEHAVIOR

(71) Applicant: INTERNATIONAL BUSINESS MACHINES CORPORATION, Armonk, NY (US)

(72) Inventors: Pranshu TIWARI, Delhi (IN); Harish BHARTI, Pune (IN); Saurabh TREHAN, Dehli (IN); Anshul CHETAL, Houston, TX (US)

(21) Appl. No.: 16/782,723

(22) Filed: Feb. 5, 2020

(51) Int. Cl. G06Q 50/06; G06Q 30/02; G06Q 50/08; G06N 20/00; G06F 16/28; G01R 21/133; H02J 13/00

(52) U.S. Cl. CPC G06Q 50/06; G06Q 30/0204; G06Q 50/08; H02J 13/00002; G06F 16/285; G01R 21/133; G06N 20/00

(57) ABSTRACT

Methods and systems for metrics for energy saving and response behavior are disclosed. A method includes: receiving, by a computing device, for each of a plurality of energy users, consumption time series data from a smart meter of the energy user; determining, by the computing device, for each of the plurality of energy users, demographic data of the energy user; clustering, by the computing device, the energy users based on the consumption time series data and the demographic data; identifying, by the computing device, a plurality of groups of energy users based upon the clustering; and determining, by the computing device, an energy saving program to associate with each of the plurality of groups.

### BACKGROUND

Aspects of the present invention generally relate to computing devices and, more particularly, to methods and systems for metrics for energy saving and response behavior.

Monitoring devices may be used to measure energy (e.g., electricity) use and performance of various appliances and other devices. A user may conserve energy by adjusting usage of the various appliances and other devices based on energy use measured by monitoring devices. Energy utilities (e.g., electric utilities and natural gas utilities) may perform pattern analysis to identify energy use patterns among various users (e.g., neighbors).

### SUMMARY

In a first aspect of the invention, there is a method that includes: receiving, by a computing device, for each of a plurality of energy users, consumption time series data from a smart meter of the energy user; determining, by the computing device, for each of the plurality of energy users, demographic data of the energy user; clustering, by the computing device, the energy users based on the consumption time series data and the demographic data; identifying, by the computing device, a plurality of groups of energy users based upon the clustering; and determining, by the computing device, an energy saving program to associate with each of the plurality of groups.

In another aspect of the invention, there is a computer program product that includes: one or more computer readable storage media, and program instructions collectively stored on the one or more computer readable storage media. The program instructions include: program instructions to receive, for each of a plurality of energy users, consumption time series data from a smart meter of the energy user; program instructions to cluster the energy users based on the consumption time series data; program instructions to identify a plurality of groups of energy users based upon the clustering; and program instructions to send a recommendation of an architectural change to improve energy efficiency to the energy users in one of the plurality of groups.

In another aspect of the invention, there is a system that includes: a hardware processor, a computer readable memory, and one or more computer readable storage media associated with a computing device; program instructions to receive, for each of a plurality of energy users, consumption time series data from a smart meter of the energy user; program instructions to determine, for each of the plurality of energy users, demographic data of the energy user; program instructions to cluster the energy users based on the consumption time series data and the demographic data; program instructions to identify a plurality of groups of energy users based upon the clustering; and program instructions to determine an energy saving program to associate with each of the plurality of groups, wherein the program instructions are stored on the one or more computer readable storage media for execution by the hardware processor via the computer readable memory.

### BRIEF DESCRIPTION OF THE DRAWINGS

Aspects of the present invention are described in the detailed description which follows, in reference to the noted plurality of drawings by way of non-limiting examples of exemplary embodiments of the present invention.

FIG. 1 depicts a computer system in accordance with aspects of the invention.

FIG. 2 depicts an illustrative environment in accordance with aspects of the invention.

FIG. 3 depicts a flowchart of an exemplary method performed in accordance with aspects of the invention.

FIG. 4 illustrates an example of a clustering dendrogram generated according to an embodiment.

FIG. 5 illustrates an example of a neural network trained according to an embodiment.

FIG. 6 shows a graph of a relationship between model complexity and error according to an embodiment.

### DETAILED DESCRIPTION

Aspects of the present invention generally relate to computing devices and, more particularly, to methods and systems for metrics for energy saving and response behavior. As described herein, aspects of the invention include a method and system that identify energy use patterns at an appliance level and select users for various energy saving programs. Additionally, as described herein, aspects of the invention include a method and system that use segmentation at the appliance level for consumer power usage and provide insights and recommendation at the appliance level. Additionally, as described herein, aspects of the invention include a method and system that use machine learning techniques to identify factors for user segmentation and segment users based on patterns. Additionally, as described herein, aspects of the invention include a method and system that leverage neural networks to identify users who may benefit from architectural or insulation improvements. Additionally, as described herein, aspects of the invention include a method and system that provide for focused energy efficiency programs, an improved customer experience, and improved operational efficiency.

Conventional methods and systems used by utilities are not able to identify patterns at the appliance level and are not able to identify different customer segments who have different levels of interest in saving energy and different energy saving opportunities available. Accordingly, utilities may not be able to successfully encourage customers to save energy. Embodiments address these problems with conventional methods and systems by providing an orchestration process that identifies segments of customers to promote and channelize particular energy saving programs. Additionally, embodiments address problems with conventional methods and system by avoiding sending too many notifications to customers, therefore improving customer experience and reducing marketing cost.

In particular, embodiments improve the functioning of a computer by providing methods and systems for metrics for energy saving and response behavior. Additionally, embodiments improve the functioning of a computer by providing a method and system that use segmentation at the appliance level for consumer power usage and provide insights and recommendation at the appliance level. Additionally, embodiments improve the functioning of a computer by providing a method and system that use machine learning techniques to identify factors for user segmentation and segment users based on patterns. Additionally, embodiments improve the functioning of a computer by providing a method and system that leverage neural networks to identify users who may benefit from architectural or insulation improvements. Additionally, embodiments improve the functioning of a computer by providing a method and system that provide for focused energy efficiency programs, an improved customer experience, and improved operational efficiency. Accordingly, through the use of rules that improve computer-related technology, implementations of the invention allow computer performance of functions not previously performable by a computer. Additionally, implementations of the invention use techniques that are, by definition, rooted in computer technology (e.g., machine learning and neural networks).

In embodiments, a combination of advanced machine learning and neural networks are used to analyze various data points about utility customers, including tree map traversal, clustering, and weight based neural networks across customer data. In embodiments, a level of success in terms of customer response to energy efficiency programs is measured using a penalized regression mechanism to identify parameters that impact customer response. In embodiments, the identified parameters are used to minimize a cost of sending energy efficiency program notifications and to target a customer segment that is most likely to respond positively to the energy efficiency program.

In embodiments, a method and system are provided that identify clusters of appliance consumption based on energy patterns for different appliance types. In embodiments, these segments and patterns are compared with other consumers with similar profiles and demographics. In embodiments, a method and system are provided that help consumers conserve energy, reduce carbon footprint, and also save on energy cost. Additionally, in embodiments, a method and system are provided that help utilities identify usage patterns to better predict demand and identify products that are best suited to particular customers.

Embodiments provide for continuous parameter identification, which are factors used to evaluate and create user segments. In embodiments, continuous parameters are attributes that are identified by the system utilizing usage data, customer profiles, weather data, and any other available data and that are used to define the user segments.

Embodiments also provide for optimum segment definition to identify energy consumption pockets. In embodiments, a k-cluster technique along with a tree map is applied for optimum segmentation. In embodiments, the tree map is used to identify the best cluster for hierarchical clustering among users against peak and average energy consumption for appliances (or other equipment) and then based on demographic factors. Embodiments also provide for targeting users for demand shift programs, energy efficiency programs, and home/building efficiency improvement programs.

Embodiments also use neural networks along with back propagation networks and deep learning efficiency groups to identify key common parameters for high energy usage user segments. Embodiments also identify home/building characteristics for home/building efficiency improvement programs. Additionally, embodiments promote energy efficiency programs by applying association rules to improve target segmentation leading to focused programs, improved customer experience, and higher conversion rates.

Embodiments also provide for optimum classification of customer responses based on correlated parameters by applying a penalized regression to re-institutionalize customer behavior metrics. Additionally, embodiments provide for a self-learning mechanism that adjusts a budget of an energy efficiency program management system by leveraging constraint/linear programming.

To the extent the implementations collect, store, or employ personal information of individuals, it should be understood that such information shall be used in accordance with all applicable laws concerning protection of personal information. Additionally, the collection, storage, and use of such information may be subject to advance notification and consent of the individual to such activity, for example, through “opt-in” or “opt-out” processes as may be appropriate for the situation and type of information. Storage and use of personal information may be in an appropriately secure manner reflective of the type of information, for example, through various encryption and anonymization techniques for particularly sensitive information.

The present invention may be a system, a method, and/or a computer program product at any possible technical detail level of integration. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium or media, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a computer or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be accomplished as one step, executed concurrently, substantially concurrently, in a partially or wholly temporally overlapping manner, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

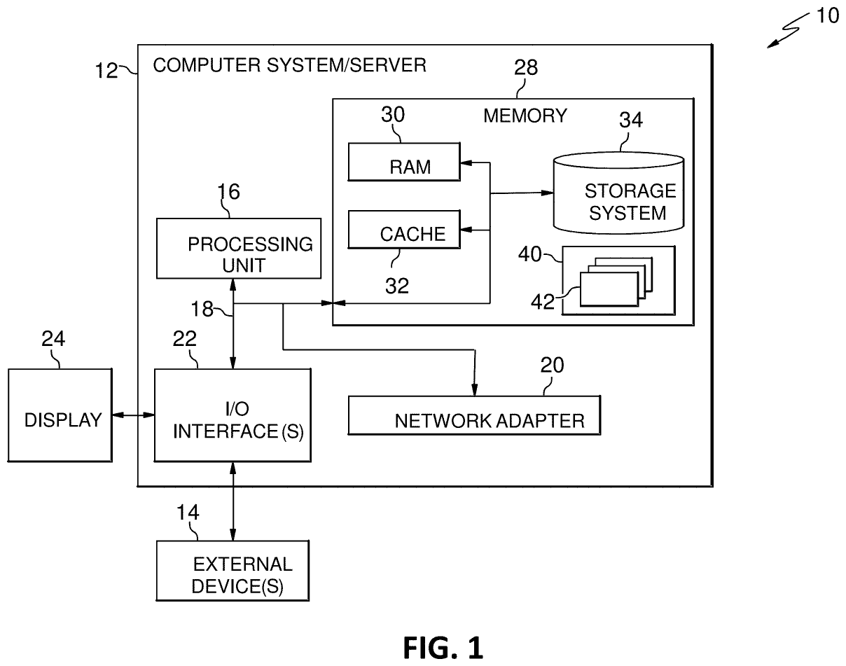

Referring now to FIG. 1, a schematic of an example of a computing infrastructure is shown. Computing infrastructure 10 is only one example of a suitable computing infrastructure and is not intended to suggest any limitation as to the scope of use or functionality of embodiments of the invention described herein. Regardless, computing infrastructure 10 is capable of being implemented and/or performing any of the functionality set forth hereinabove.

In computing infrastructure 10 there is a computer system (or server) 12, which is operational with numerous other general purpose or special purpose computing system environments or configurations. Examples of well-known computing systems, environments, and/or configurations that may be suitable for use with computer system 12 include, but are not limited to, personal computer systems, server computer systems, thin clients, thick clients, hand-held or laptop devices, multiprocessor systems, microprocessor-based systems, set top boxes, programmable consumer electronics, network PCs, minicomputer systems, mainframe computer systems, and distributed cloud computing environments that include any of the above systems or devices, and the like.

Computer system 12 may be described in the general context of computer system executable instructions, such as program modules, being executed by a computer system. Generally, program modules may include routines, programs, objects, components, logic, data structures, and so on that perform particular tasks or implement particular abstract data types.

Computer system 12 may be practiced in distributed cloud computing environments where tasks are performed by remote processing devices that are linked through a communications network. In a distributed cloud computing environment, program modules may be located in both local and remote computer system storage media including memory storage devices.

As shown in FIG. 1, computer system 12 in computing infrastructure 10 is shown in the form of a general-purpose computing device. The components of computer system 12 may include, but are not limited to, one or more processors or processing units (e.g., CPU) 16, a system memory 28, and a bus 18 that couples various system components including system memory 28 to processor 16.

Bus 18 represents one or more of any of several types of bus structures, including a memory bus or memory controller, a peripheral bus, an accelerated graphics port, and a processor or local bus using any of a variety of bus architectures. By way of example, and not limitation, such architectures include Industry Standard Architecture (ISA) bus, Micro Channel Architecture (MCA) bus, Enhanced ISA (EISA) bus, Video Electronics Standards Association (VESA) local bus, and Peripheral Component Interconnects (PCI) bus.

Computer system 12 typically includes a variety of computer system readable media. Such media may be any available media that is accessible by computer system 12, and it includes both volatile and non-volatile media, removable and non-removable media.

System memory 28 can include computer system readable media in the form of volatile memory, such as random access memory (RAM) 30 and/or cache memory 32. Computer system 12 may further include other removable/non-removable, volatile/non-volatile computer system storage media. By way of example only, storage system 34 can be provided for reading from and writing to a nonremovable, non-volatile magnetic media (not shown and typically called a “hard drive”). Although not shown, a magnetic disk drive for reading from and writing to a removable, non-volatile magnetic disk (e.g., a “floppy disk”), and an optical disk drive for reading from or writing to a removable, non-volatile optical disk such as a CD-ROM, DVD-ROM or other optical media can be provided. In such instances, each can be connected to bus 18 by one or more data media interfaces. As will be further depicted and described below, memory 28 may include at least one program product having a set (e.g., at least one) of program modules that are configured to carry out the functions of embodiments of the invention.

Program/utility 40, having a set (at least one) of program modules 42, may be stored in memory 28 by way of example, and not limitation, as well as an operating system, one or more application programs, other program modules, and program data. Each of the operating system, one or more application programs, other program modules, and program data or some combination thereof, may include an implementation of a networking environment. Program modules 42 generally carry out the functions and/or methodologies of embodiments of the invention as described herein.

Computer system 12 may also communicate with one or more external devices 14 such as a keyboard, a pointing device, a display 24, etc.; one or more devices that enable a user to interact with computer system 12; and/or any devices (e.g., network card, modem, etc.) that enable computer system 12 to communicate with one or more other computing devices. Such communication can occur via Input/Output (I/O) interfaces 22. Still yet, computer system 12 can communicate with one or more networks such as a local area network (LAN), a general wide area network (WAN), and/or a public network (e.g., the Internet) via network adapter 20. As depicted, network adapter 20 communicates with the other components of computer system 12 via bus 18. It should be understood that although not shown, other hardware and/or software components could be used in conjunction with computer system 12. Examples, include, but are not limited to: microcode, device drivers, redundant processing units, external disk drive arrays, RAID systems, tape drives, and data archival storage systems, etc.

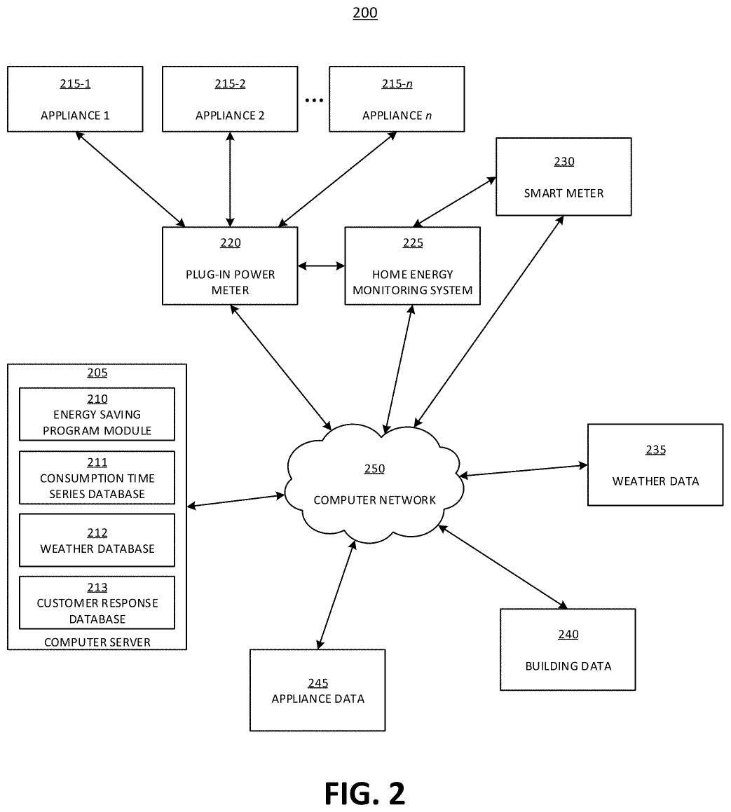

FIG. 2 depicts an illustrative environment 200 in accordance with aspects of the invention. As shown, the environment 200 comprises a computer server 205, a plurality of appliances 215-1, 215-2, . . . , 215-n, a plug-in power meter 220, a home energy monitoring system 225, a smart meter 230, weather data 235, building data 240, and appliance data 245 which are in communication via a computer network 250. In embodiments, the computer network 250 is any suitable network including any combination of a LAN, WAN, or the Internet. In embodiments, the computer server 205, the plurality of appliances 215-1, 215-2, . . . , 215-n, the plug-in power meter 220, the home energy monitoring system 225, the smart meter 230, the weather data 235, the building data 240, and the appliance data 245 are physically collocated, or, more typically, are situated in separate physical locations.

The quantity of devices and/or networks in the environment 200 is not limited to what is shown in FIG. 2. In practice, the environment 200 may include additional devices and/or networks; fewer devices and/or networks; different devices and/or networks; or differently arranged devices and/or networks than illustrated in FIG. 2. Also, in some implementations, one or more of the devices of the environment 200 may perform one or more functions described as being performed by another one or more of the devices of the environment 200.

In embodiments, the computer server 205 is a computer device comprising one or more elements of the computer system/server 12 (as shown in FIG. 1). In particular, the computer server 205 is implemented as hardware and/or software using components such as mainframes; RISC (Reduced Instruction Set Computer) architecture based servers; servers; blade servers; storage devices; networks and networking components; virtual servers; virtual storage; virtual networks, including virtual private networks; virtual applications and operating systems; and virtual clients.

In embodiments, the computer server 205 includes an energy saving program module 210, which comprises one or more of the program modules 42 shown in FIG. 1. In embodiments, the energy saving program module 210 includes program instructions for identifying energy use patterns at an appliance level and selecting users for various energy saving programs. In embodiments, the program instructions included in the energy saving program module 210 of the computer server 210 are executed by one or more hardware processors.

Additionally, in embodiments, the computer server 205 includes a consumption time series database 211 that stores consumption time series data, a weather database 212 that stores weather data, and a customer response database 213 that stores data regarding customer responses to energy efficiency programs. In embodiments, each of the consumption time series database 211, the weather database 212, and the customer response database 213 is implemented as hardware and/or software using components such as relational databases, non-relational databases, and/or storage devices.

Still referring to FIG. 2, in embodiments, each of the appliances 215-1, 215-2, . . . , 215-n is an appliance (e.g., an air conditioner, refrigerator, freezer, washer, dryer, dishwasher, cooktop, oven, range, etc.) or other energy-consuming device that is present in a building (e.g., office, store, apartment, house, etc.) of an energy user. In embodiments, each of the appliances 215-1, 215-2, . . . , 215-n is connected to (e.g., a power cord is plugged into) or otherwise in communication with the plug-in power meter 220, which is connected to (e.g., via network 250) or otherwise in communication with the home energy monitoring system 225. In other embodiments, one or more of the appliances 215-1, 215-2, . . . , 215-n is connected to (e.g., via the network 250) the home energy monitoring system 225, bypassing the plug-in power meter 220.

Still referring to FIG. 2, in embodiments, the plug-in power meter 220 measures energy use (e.g., electricity use in kWh) of the connected appliances 215-1, 215-2, . . . , 215-n. In embodiments, the plug-in power meter 220 reports the measured energy use of the connected appliances 215-1, 215-2, . . . , 215-n to the home energy monitoring system 225, either at predetermined intervals, in response to a request from the home energy monitoring system 225, or in response to changes in energy use by the connected appliances 215-1, 215-2, . . . , 215-n.

Still referring to FIG. 2, in embodiments, the smart meter 230 measures the overall energy use of an energy user (e.g., all of the energy used by a building such as an office, store, apartment, house, etc.) and reports the overall energy use to the energy saving program module 210 of the computer server 205 as consumption time series data. Additionally, in embodiments, the smart meter 230 receives information about appliance-level energy use (e.g., energy use by the appliances 215-1, 215-2, . . . , 215-n) from the home energy monitoring system 225 and reports the appliance-level energy use to the energy saving program module 210 of the computer server 205 as consumption time series data. In other embodiments, the home energy monitoring system 225 directly reports the appliance-level energy use to the energy saving program module 210 of the computer server 205 as consumption time series data. The consumption time series data may be stored in the consumption time series database 211 of the computer server 205.

Still referring to FIG. 2, in embodiments, each of the weather data 235, the building data 240, and the appliance data 245 is a computer device comprising one or more elements of the computer system/server 12 (as shown in FIG. 1). In particular, each of the weather data 235, the building data 240, and the appliance data 245 is implemented as hardware and/or software using components such as mainframes; RISC (Reduced Instruction Set Computer) architecture based servers; servers; blade servers; storage devices; networks and networking components; virtual servers; virtual storage; virtual networks, including virtual private networks; virtual applications and operating systems; and virtual clients. In embodiments, the weather data 235 provides weather data to the energy saving program module 210 of the computer server 205. In embodiments, the building data 240 provides building data to the energy saving program module 210 of the computer server 205. In embodiments, the appliance data 245 provides appliance data to the energy saving program module 210 of the computer server 205.

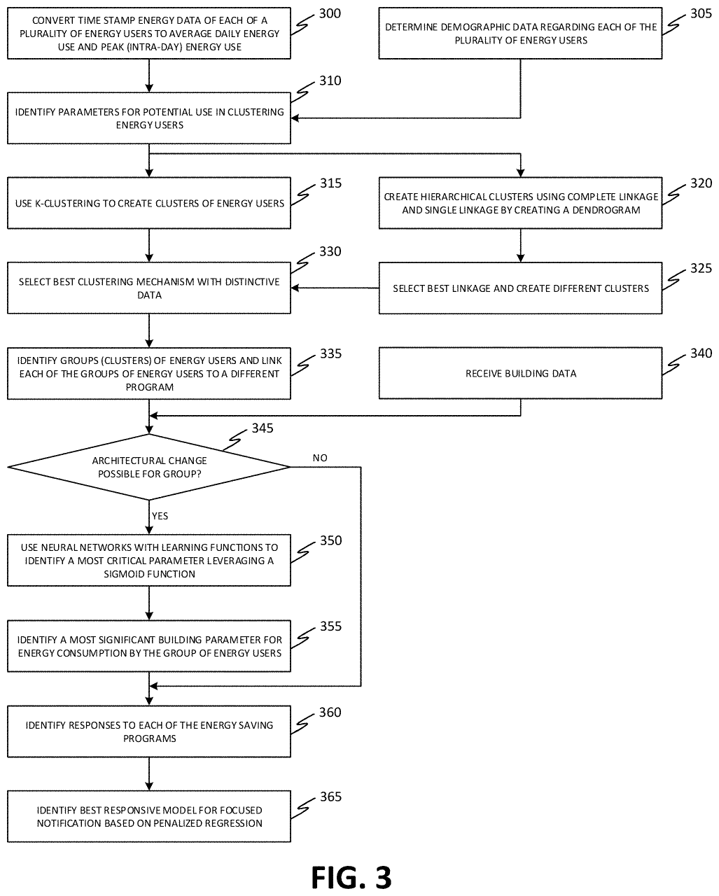

FIG. 3 depicts a flowchart of an exemplary method performed by the energy saving program module 210 of the computer server 205 in accordance with aspects of the invention. The steps of the method may be performed in the environment of FIG. 2 and are described with reference to the elements shown in FIG. 2.

At step 300, the computer server 205 converts time stamp energy data of each of a plurality of energy users to average daily energy use and peak (intra-day) energy use. In embodiments, step 300 comprises the energy saving program module 210 of the computer server 205 receiving, from each of the plurality of energy users (customers), consumption time series data (time stamp energy data) from the smart meter 230 of the energy user and/or the home energy monitoring system 225 of the energy user, storing the consumption time series data in the consumption time series database 211 of the computer server 205, and converting the received consumption time series data to average daily energy use and peak (intra-day) energy use.

Still referring to FIG. 3, at step 305, the computer server 205 determines demographic data regarding each of the plurality of energy users. In embodiments, step 300 comprises the energy saving program module 210 of the computer server 205 determining demographic data including a plurality of items of demographic information (e.g., demographic variables such as a number of household members, age, etc.) for each of the plurality of energy users.

Still referring to FIG. 3, at step 310, the computer server 205 identifies parameters for potential use in clustering the energy users. In embodiments, step 310 comprises the energy saving program module 210 of the computer server 205 identifying the parameters for potential use in clustering the energy users based on the average daily energy use and peak (intra-day) energy use and weather data from the weather database 212, the demographic data from step 305, and appliance data from appliance data 245. In embodiments, the weather data may be received from the weather data 235 and stored in the weather database 212.

Still referring to FIG. 3, at step 315, the computer server 205 uses k-clustering to create clusters of energy users. In embodiments, step 315 comprises the energy saving program module 210 of the computer server 205 using k-clustering to create clusters of energy users for k=1, 2, 3, and 4 based on the average daily energy use and peak (intra-day) energy use from step 300, the demographic data from step 305, and the parameters from step 310. In embodiments, the clustering is used to identify energy consumption pockets (i.e., clusters of energy users with similar energy consumption profiles or attributes).

Still referring to step 315, in embodiments, the energy saving program module 210 uses p variables to cluster the data. In embodiments, there is no response variable or predictor variable, and therefore the energy saving program module 210 uses unsupervised learning to identify segments of appliance-based energy segmentation. In particular, each energy user in their time index is c1, and the following properties are exhibited:

c1∪c2∪c3∪ . . . ck=(1 . . . n clusters}

cₖ∩c_{k′} for all k≠k′

Still referring to step 315, in embodiments, X represents a matrix

$$[ \begin{matrix}{x}_{11} & {x}_{1 p} \\ {xx}_{n 1} & {x}_{np}\end{matrix} ]$$

where there are p variables—demographic variable 1, demographic variable 2, demographic variable 3, average energy use of appliance 1, average energy use of large appliances, average energy use of appliance 3, etc. In embodiments, within cluster variation=Min{Σₖ₌₁^{K}W(Ck)} where, according to Equation 1:

=>W(C_{K})=1/|cₖ|Σ_{i,i′in ck}^{All}Σⱼ₌₁^{P}(xᵢⱼ−x_{i′j})² Equaation 1

Still referring to FIG. 3, at step 320, the computer server 205 creates hierarchical clusters using complete linkage and single linkage by creating a dendrogram. In embodiments, step 320 comprises the energy saving program module 210 of the computer server 205 creating the hierarchical clusters using complete linkage and single linkage by creating the dendrogram based on the average daily energy use and peak (intra-day) energy use from step 300, the demographic data from step 305, and the parameters from step 310. In embodiments, the clustering is used to identify energy consumption pockets (i.e., clusters of energy users with similar energy consumption profiles or attributes).

Still referring to step 320, in embodiments, the energy saving program module 210 minimizes intragroup distances using complete linkage according to Equation 2:

$$DCL ( G , H ) {{Min}_{i ∈ G}}_{\hat{ι} ∈ H} {d}_{i , {ι}^{′} } where {ι}^{'} ∈ G \& ι {∈}^{'} H$$

where GUI are two groups and Equation 2 d is the intergroup distance between 2′ . . . points between two groups

Still referring to step 320, in embodiments, the energy saving program module 210 minimizes intragroup distances using single linkage according to Equation 3:

$$\begin{matrix}DSL ( G < H ) = {{MIN}_{i ∈ G}}_{\hat{ι} ∈ H} {d}_{i , {ι}^{′}} \\ where d is the integroup distance between 2 groups & Equation 3\end{matrix}$$

Still referring to FIG. 3, at step 325, the computer server 205 selects the best linkage and creates different clusters. In embodiments, step 325 comprises the energy saving program module 210 of the computer server 205 selecting the best linkage from step 320 and creating different clusters. In particular, in embodiments, the energy saving program module 210 uses a tree map to identify the best clusters for hierarchical clustering among energy users against peak and average energy consumption for appliances and also based on demographic data determined at step 305. In embodiments, the tree map is used to identify the number of clusters needed to differentiate different groups of energy users. In embodiments, a clustering dendrogram shows the height at which clusters may be differentiated with minimal overlapping based on complete linkage.

Still referring to FIG. 3, at step 330, the computer server 205 selects the best clustering mechanism with distinctive data. In embodiments, step 330 comprises the energy saving program module 210 of the computer server 205 selecting the best clustering mechanism with distinctive data. In particular, in embodiments, the energy saving program module 210 compares the clusters created at steps 315 and 325 to determine which clustering mechanism generated the best clusters, e.g., based on minimal overlap and maximum separation.

Still referring to FIG. 3, at step 335, the computer server 205 identifies the groups (clusters) of energy users and links each of the groups of energy users to a different program. In embodiments, step 335 comprises the energy saving program module 210 of the computer server 205 associating an energy saving program with each of the groups of energy users and determining which energy users are in each of the groups.

Still referring to step 335, in an example, a first group includes energy users with high peak energy use and high average energy use and a first range of values for a first demographic variable. A second group includes energy users with high peak energy use and low average energy use for appliances and a second range of values for the first demographic variable. A third group includes energy users with high average energy use, low energy use for appliances, and a third range of values for the first demographic variable. A fourth group includes energy users with high average energy use, high energy use for heating and cooling devices, and the third range of values for the first demographic variable. In the example, the first and fourth groups are linked to a program promoting energy efficient equipment, the second and third groups are linked to a program promoting energy efficient practices, and the second group is linked to a demand shifting program. In embodiments, the energy saving program module 210 implements the energy saving programs assigned to each of the groups, e.g., by sending communications regarding the programs to the energy users in the groups.

Still referring to FIG. 3, at step 340, the computer server 205 receives building data. In embodiments, step 340 comprises the energy saving program module 210 of the computer server 205 receiving building data for the energy users from the building data 240. In particular, the building data includes information about architectural characteristics of buildings associated with the energy users (e.g., types of windows, insulation, etc.). The building data received at step 340 may also include information about a number of occupants, building construction, relative compactness, surface area, wall area, roof area, overall height, orientation, glazing area, and glazing area distribution.

Still referring to FIG. 3, at step 345, the computer server 205 determines whether or not an architectural change is possible for the group. In embodiments, step 345 comprises the energy saving program module 210 of the computer server 205 using the building data received at step 340 to determine whether or not an architectural change (e.g., replacing windows, adding insulation, etc.) is possible for energy users within a particular group identified at step 335. In particular, at step 345, the energy saving program module 210 of the computer server 205 determines that an architectural change is possible for the group if the building data received at step 340 indicates one or more inefficient building features (e.g., types of windows, insulation, etc.). If the energy saving program module determines that the architectural change is possible, then the flow proceeds to step 350. On the other hand, if the energy saving program module determines that the architectural change is not possible, then the flow proceeds to step 360.

Still referring to FIG. 3, at step 350, the computer server 205 uses neural networks with learning functions to identify a most critical parameter leveraging a sigmoid function. In embodiments, step 350 comprises the energy saving program module 210 of the computer server 205 using neural networks with learning functions to identify the most critical parameter leveraging a sigmoid function according to Equation 4:

f(zⱼ)=e^{zj}/(1+e^{zi}) where z is the linear value at each neural node/hidden node for i-th variable Equation 4

Still referring to step 350, in embodiments, the energy saving program module 210 assigns random weights and then readjusts the weights. Accordingly, the energy saving program module 210 calculates the cross entropy (deviance) according to Equation 5, where R(θ) is minimized by gradient descent called backpropagation:

R(θ)=Σ₁ⁿΣ₁ⁿz log fₖ(xi) Equation 5

Still referring to FIG. 3, at step 355, the computer server 205 identifies a most significant building parameter for energy consumption by the group of energy users. In embodiments, step 355 comprises the energy saving program module 210 of the computer server 205 identifying a most significant building parameter for energy consumption by the group of energy users using a neural network, where each input variable gives output as nodes with one hidden layer. Next, the energy saving program module 210 creates an importance factor of predictor variables (building parameters) for each output/cluster number. In this manner, the energy saving program module 210 identifies within a training data set key building parameters that are responsible for high energy consumption. In embodiments, the energy saving program module 210 sends communications to the users recommending an architectural change to improve energy efficiency based on the key building parameters that are responsible for high energy consumption. In embodiments, the energy saving program module 210 uses a confusion matrix based on neural networks to classify which energy users are likely to fall under the group based on building parameters.

Still referring to FIG. 3, at step 360, the computer server 205 identifies responses to each of the energy saving programs. In embodiments, step 360 comprises the energy saving program module 210 of the computer server 205 identifying the responses of the energy users to the energy saving programs to which the groups were linked at step 335 by using association rules and storing the responses in the customer response database 213 in the computer server 205. In particular, in embodiments, the energy saving program module 210 of the computer server 205 creates a matrix/data frame for each of the energy saving programs, represented by M, where the column C represents the different categorical variables showing the energy saving program against energy user indices:

$$Matrix M = \begin{matrix}{a}_{11} & {a}_{1 n} & {C}_{1} {b}_{1} \\ {a}_{21} & {a}_{2 n} & {C}_{1} {b}_{2} \\ {a}_{m 1} & {a}_{m n} & {C}_{1} {b}_{m}\end{matrix}$$

Still referring to step 360, in embodiments, in M, b is the response variable over a period (e.g., 6 months) measuring the response denoted as b=[0,1,2]. In an example, b=0 if there was no response, b=1 if there was a neutral response, and b=2 if there was a positive response (e.g., an energy user installs a smart thermostat or improves the insulation of their house).

Still referring to step 360, in embodiments, B represents a response to a program. In an example, in order to determine a probability that person has a high average energy and would benefit from installing a smart thermostat or insulating their house, the energy saving program module 210 categorizes data into a binary algorithm to compute the antecedents and consequents according to Equation 6, below. In embodiments, let (T(A-→B)=P(A) & P(B), where P(A) represents the antecedents that pertain to high peak energy usage and B represents a response to an energy saving program.

$$C ( A = > B ) = \frac{T ( A = > B )}{T ( A )} \qquad Equation 6$$

Still referring to step 360, in embodiments, the energy saving program module 210 leverages the antecedents and consequents in matrix M to calculate lift according to Equation 7:

$$L ( A = > B ) = \frac{C ( A = > B )}{T ( B )} \qquad Equation 7$$

Still referring to FIG. 3, at step 365, the computer server 205 identifies the best responsive model for focused notification based on penalized regression. In embodiments, step 365 comprises the energy saving program module 210 of the computer server 205 measuring success of a response by energy users to the energy saving programs based on parametric supervised learning using single fold cross-validation and applying ridge/lasso regression across the building data and demographic parameters.

Still referring to step 365, in embodiments, the energy saving program module 210 allocates i to an energy user who makes a change or responds positively to an energy efficiency program after predetermine period (e.g., 3 months), where i=0 indicates no response and i=1 indicates a response. In an example, the energy saving program module 210 uses 128 predictors, and key variables are determined to ensure that models are well fit at the cost of lower bias. In embodiments, the energy saving program module 210 reduces the coefficient of estimate to reduce variance and avoid overfitting the model. In embodiments, the energy saving program module 210 selects a model to optimize bias and variance to minimize the error of misclassification. In embodiments, in the ridge regression, misclassification is determined according to Equation 8:

$$\begin{matrix}{β}_{r i d g e} Misclassification Error = {\sum }_{1}^{N} {y}_{i} \neq \\ = {( {\sum }_{1}^{N} {y}_{i} - {β}_{0} - {\sum }_{j = 1}^{p} {β}_{j} * {x}_{i j} )}^{2} + Φ {\sum }_{j = 1}^{p} {β}_{j}^{2} \\ = ( {y}_{i} - {β}_{j}^{T} X ) ( {y}_{i} - {β}_{j} + Φ {\sum }_{j = 1}^{p} {β}_{{j}^{2}}^{2}\end{matrix} \qquad Equation 8$$

[Matrix form of same equation]

Values of

$${β}_{ridg e} = [ \begin{matrix}{β}_{ridg e 1} \\ {β}_{ridg e 2} \\ {β}_{ridg e 2} 3\end{matrix} ] dep on values of Φ$$

Still referring to step 365, in embodiments, based on ridge regression and considering ϕ=exp((100:−100)/100) w, the energy saving program module 210 determines coefficient pathways. Since misclassification is function of ϕ, the energy saving program module 210 chooses the best ϕ to reduce the misclassification rate. Hence, the energy saving program module 210 chooses the value of β_{ridge} which has lowest misclassification. In this manner, the energy saving program module 210 measures the success of a response by energy users to the energy saving programs. The measured success may be used by the energy saving program module 210 as feedback to improve future programs.

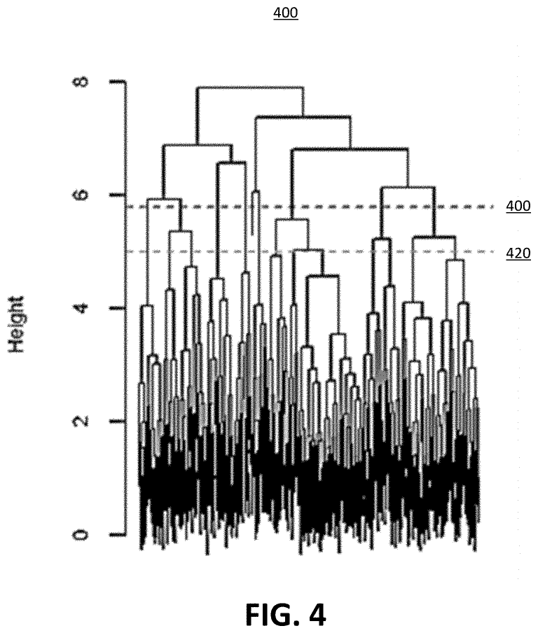

FIG. 4 illustrates an example of a clustering dendrogram 400 generated according to an embodiment by the energy saving program module 210 as described above with respect to step 325 of FIG. 3. The dashed lines 410, 420 in the clustering dendrogram 400 show heights at which clusters may be differentiated with minimal overlapping based on complete linkage.

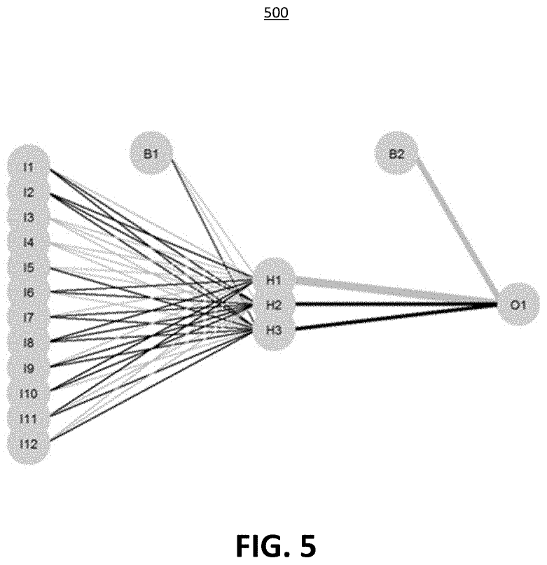

FIG. 5 illustrates an example of a neural network 500 trained according to an embodiment by the energy saving program module 210 as described above with respect to step 355 of FIG. 3. The energy saving program module 210 uses the neural network 500 to identify a most significant building parameter for energy consumption by the group of energy users.

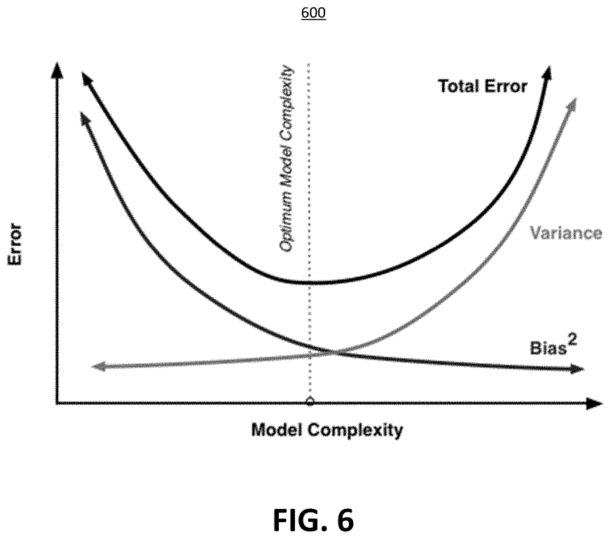

FIG. 6 shows a graph 600 of a relationship between model complexity and error according to an embodiment. In embodiments, the energy saving program module 210 selects a model by optimizing bias and variance to minimize the error of misclassification.

In embodiments, a service provider could offer to perform the processes described herein. In this case, the service provider can create, maintain, deploy, support, etc., the computer infrastructure that performs the process steps of the invention for one or more customers. These customers may be, for example, any business that uses cloud computing technology. In return, the service provider can receive payment from the customer(s) under a subscription and/or fee agreement and/or the service provider can receive payment from the sale of advertising content to one or more third parties.

In still additional embodiments, the invention provides a computer-implemented method, via a network. In this case, a computer infrastructure, such as computer system/server 12 (FIG. 1), can be provided and one or more systems for performing the processes of the invention can be obtained (e.g., created, purchased, used, modified, etc.) and deployed to the computer infrastructure. To this extent, the deployment of a system can comprise one or more of: (1) installing program code on a computing device, such as computer system/server 12 (as shown in FIG. 1), from a computer-readable medium; (2) adding one or more computing devices to the computer infrastructure; and (3) incorporating and/or modifying one or more existing systems of the computer infrastructure to enable the computer infrastructure to perform the processes of the invention.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method comprising:
receiving, by a computing device, for each of a plurality of energy users, consumption time series data from a smart meter of the energy user;
determining, by the computing device, for each of the plurality of energy users, demographic data of the energy user;
clustering, by the computing device, the energy users based on the consumption time series data and the demographic data;
identifying, by the computing device, a plurality of groups of energy users based upon the clustering; and
determining, by the computing device, an energy saving program to associate with each of the plurality of groups.

2. The method according to claim 1, wherein the consumption time series data comprises information about appliance-level energy use.

3. The method according to claim 2, wherein the information about appliance-level energy use is measured by a plug-in power meter.

4. The method according to claim 1, wherein the clustering comprises using k-clustering to create clusters based on average daily energy use and peak energy use determined using the consumption time series data.

5. The method according to claim 1, wherein the clustering comprises creating hierarchical clusters using complete linkage and single linkage based on average daily energy use and peak energy use determined using the consumption time series data.

6. The method according to claim 1, further comprising sending, by the computing device, for each of the plurality of groups, communications regarding the energy saving program to the energy users in the group.

7. The method according to claim 1, further comprising sending, by the computing device, a recommendation of an architectural change to improve energy efficiency to the energy users in one of the plurality of groups.

8. A computer program product comprising:
one or more computer readable storage media, and program instructions collectively stored on the one or more computer readable storage media, the program instructions comprising:
program instructions to receive, for each of a plurality of energy users, consumption time series data from a smart meter of the energy user;
program instructions to cluster the energy users based on the consumption time series data;
program instructions to identify a plurality of groups of energy users based upon the clustering; and
program instructions to send a recommendation of an architectural change to improve energy efficiency to the energy users in one of the plurality of groups.

9. The computer program product according to claim 8, wherein the consumption time series data comprises information about appliance-level energy use.

10. The computer program product according to claim 9, wherein the information about appliance-level energy use is measured by a plug-in power meter.

11. The computer program product according to claim 8, wherein the clustering comprises using k-clustering to create clusters based on average daily energy use and peak energy use determined using the consumption time series data.

12. The computer program product according to claim 8, wherein the clustering comprises creating hierarchical clusters using complete linkage and single linkage based on average daily energy use and peak energy use determined using the consumption time series data.

13. The computer program product according to claim 8, further comprising program instructions to send, for each of the plurality of groups, communications regarding energy saving programs to the energy users in each of the plurality of groups.

14. A system comprising:
a hardware processor, a computer readable memory, and one or more computer readable storage media associated with a computing device;
program instructions to receive, for each of a plurality of energy users, consumption time series data from a smart meter of the energy user;
program instructions to determine, for each of the plurality of energy users, demographic data of the energy user;
program instructions to cluster the energy users based on the consumption time series data and the demographic data;
program instructions to identify a plurality of groups of energy users based upon the clustering; and
program instructions to determine an energy saving program to associate with each of the plurality of groups,
wherein the program instructions are stored on the one or more computer readable storage media for execution by the hardware processor via the computer readable memory.

15. The system according to claim 14, wherein the consumption time series data comprises information about appliance-level energy use.

16. The system according to claim 15, wherein the information about appliance-level energy use is measured by a plug-in power meter.

17. The system according to claim 14, wherein the clustering comprises using k-clustering to create clusters based on average daily energy use and peak energy use determined using the consumption time series data.

18. The system according to claim 14, wherein the clustering comprises creating hierarchical clusters using complete linkage and single linkage based on average daily energy use and peak energy use determined using the consumption time series data.

19. The system according to claim 14, further comprising program instructions to send, for each of the plurality of groups, communications regarding the energy saving program to the energy users in the group.

20. The system according to claim 14, further comprising program instructions to send a recommendation of an architectural change to improve energy efficiency to the energy users in one of the plurality of groups.
